(19) United States
(12) Patent Application Publication
(10) Pub. No.: US 2025/0040260 A1
(43) Pub. Date: Jan. 30, 2025

(54) BIPV-APPLICABLE HIGH-POWER SHINGLED PHOTOVOLTAIC MODULE AND MANUFACTURING METHOD THEREFOR

(71) Applicant: KOREA INSTITUTE OF INDUSTRIAL TECHNOLOGY, Cheonan-si, Chungcheongnam-do (KR)

(72) Inventors: Chae Hwan JEONG, Gwangju (KR); Sung Min YOUN, Gwangju (KR); Min Joon PARK, Gwangju (KR)

(21) Appl. No.: 18/715,734

(22) PCT Filed: Nov. 22, 2022
(86) PCT No.: PCT/KR2022/018442

§ 371 Date: Jun. 3, 2024

(30) Foreign Application Priority Data
Dec. 3, 2021 (KR) 10-2021-0171435

(51) Int. Cl. H01L 31/049; H01L 31/0216; H01L 31/024

(52) U.S. Cl. CPC H01L 31/049; H01L 31/02167; H01L 31/024

(57) ABSTRACT

Disclosed are a BIPV-applicable high-power shingled photovoltaic module and a manufacturing method therefor, the module comprising: a solar panel having a shingled array structure; a first sealant stacked on the solar panel so as to protect the solar panel; a second sealant stacked under the solar panel in order to protect the solar panel; a front cover through which the sunlight passes, and which is stacked on the first sealant so as to protect the first sealant; and a first back sheet stacked under the second sealant in order to protect the solar panel from the outside environment, and thus aesthetic impression and reflectance reduction of a high-power shingled photovoltaic module are increased so that use as an external design element of a building is possible.

### TECHNICAL FIELD

The present invention relates to a high-power shingled photovoltaic module applicable to building-integrated photovoltaics (BIPV), and a method of manufacturing the same, and more particularly, to a high-power shingled photovoltaic module applicable to BIPV, which improves the heat dissipation characteristics of a module caused by a high light absorption rate of an aesthetic pattern cover in soundproof walls, BIPV, agricultural solar power generation facilities, or the like, and a method of manufacturing the same.

### BACKGROUND ART

Recently, the popularity of solar energy as a form of clean energy has been increasing. In addition, advances in semiconductor technologies have made it possible to design photovoltaic modules and solar panels that can be more efficient and can achieve greater efficiency. In addition, materials used to manufacture photovoltaic modules and solar panels have become relatively inexpensive, thereby contributing to reducing the production costs of solar power generation.

The photovoltaic module has a multi-layer structure to protect solar cells from the external environment. A photovoltaic module frame maintains the mechanical strength of a photovoltaic module and serves to strongly bond solar cells and materials stacked on the front and rear surfaces of the solar cells.

Meanwhile, a photovoltaic module is constituted by connecting a plurality of strings in series. For example, 4 to 6 strings constitute one photovoltaic module, and each photovoltaic module has an independent solar power generation function. The string is bonded by manufacturing a busbar on each of a lower portion and an upper portion of the divided strip and connecting these busbars with an electrically conductive adhesive (ECA).

The demand for building material-integrated photovoltaic modules is increasing in various fields for applying photovoltaic modules as described above to building facades. However, in existing photovoltaic modules, due to the weight of about 14 kg of glass, there is a growing need to develop a building material photovoltaic module that may implement high power while securing durability/safety.

In addition, the demand for photovoltaic modules is increasing in various fields, and there is a growing need for a lightweight module that replaces existing photovoltaic modules due to the weight of glass. In addition, as a module is used in building-integrated photovoltaics (BIPV), since a black backsheet is used to improve module aesthetics, an additional factor occurs due to an increase in module temperature.

An example of such a technology is disclosed in Patent Documents 1 to 3 below.

For example, Patent Document 1 (Korean Patent Registration No. 10-2258304, registered on May 25, 2021) discloses a photovoltaic module for building-integrated solar power generation including a base plate formed of a steel plate material, an insulating layer formed on an upper end of the base plate to provide electrical insulation, a protective layer attached to an upper end of the insulating layer, a rear encapsulation layer formed on an upper end of the protective layer, a plurality of solar cells attached to an upper end of the rear encapsulation layer, a color encapsulation layer formed on an upper end of the solar cell, and a front protective layer attached to an upper end of the color encapsulation layer to protect an outer surface of the photovoltaic module.

In addition, Patent Document 2 below (Korean Patent Registration No. 10-1437438 (registered on Aug. 28, 2014) discloses a lightweight solar cell module including a solar panel, an ethylene vinyl acetate (EVA) sheet attached to each of both surfaces of the solar panel, a transparent substrate disposed in a front direction of the solar panel and attached to the EVA sheet, a backsheet disposed in a rear direction of the solar panel and attached to the EVA sheet, and a module frame that accommodates a combined module of the solar panel, the EVA sheet, the transparent substrate, and the backsheet therein and coupled, wherein the transparent substrate is formed of a transparent plastic material, and the module frame is formed of polyimide or polyamide.

Meanwhile, Patent Document 3 below (Korean Patent Publication No. 2020-0079788, published on Jul. 6, 2020) discloses a composite plastic film for replacing front glass of a thin film solar cell, including a polyester base film facing an encapsulant of a photovoltaic module, and at least one light capture layer formed on the polyester substrate film and selected from a patterning layer and a mat coating layer, wherein the polyester substrate film includes an ultra-violet (UV) blocking agent that blocks UVA and UVB.

### DISCLOSURE

### Technical Problem

Patent Document 1 as described above discloses a technology that can increase aesthetic characteristics as well as power generation performance, but since a module is manufactured as a building material-integrated type, there are problems in the inability to provide convenience of construction and heat dissipation characteristics.

In addition, a technology disclosed in Patent Document 2 discloses a lightweight module in which front glass is replaced with transparent plastic selected from the group consisting of ethylene tetrafluoroethylene (ETFE), polyethylene terephthalate (PET), polyethylene naphthalate (PEN), polypropylene (PP), polycarbonate (PC), polystylene (PS), polyoxyethylene (POM), acrylonitrile styrene (AS) copolymer resin, acrylonitrile butadiene styrene (ABS) copolymer resin, and triacetyl cellulose (TAC), and in Patent Document 3, a composite plastic film is provided to replace front glass of a thin film solar cell in order to reduce manufacturing costs and considerably reduce the weight of a photovoltaic module. However, Patent Documents 2 and 3 also have a problem of not being able to solve aesthetic pattern, heat dissipation characteristic, and weight reduction problems at the same time.

In other words, in the related art described above, a building material-integrated photovoltaic module is manufactured in the form of a ground-based photovoltaic module (frame, front glass, and rear backsheet) with a uniform design and high reflectance, and recently, as the building-integrated photovoltaics (BIPV) market has been revitalized centering on buildings, due to an increase in consumer needs, there has been a problem in that aesthetics, reflectance reduction, and power cannot be secured at the same time.

The present invention is intended to solve the problems described above and directed to providing a high-power shingled photovoltaic module applicable to BIPV, which is capable of simultaneously improving aesthetics, reducing reflectance, and solving power degradation due to a temperature, and a method of manufacturing the same.

The present invention is also directed to providing a high-power shingled photovoltaic module applicable to BIPV, which is easy to install and construct, is capable of preventing power degradation due to a module temperature rise, and is capable of securing mass production as compared to existing modules by manufacturing a lightweight module through one-step lamination process, and a method of manufacturing the same.

The present invention is also directed to providing a high-power shingled solar module applicable to BIPV, in which a stack of a stacked solar modules is vacuum-pressed at high temperature, thereby shortening a manufacturing time, and a method of manufacturing the same.

The present invention is also directed to providing a high-power shingled solar module applicable to BIPV, which is capable of providing convenience of construction by manufacturing a module as a solid and lightweight building material-integrated type, and a method of manufacturing the same.

### Technical Solution

In order to achieve the above object, a high-power shingled photovoltaic module applicable to BIPV according to the present invention includes a solar panel having a shingled array structure, a first sealant stacked on the solar panel to protect the solar panel, a second sealant stacked below the solar panel to protect the solar panel, a front cover stacked on the first sealant to transmit sunlight and protect the first sealant, and a first backsheet stacked below the second sealant to protect the solar panel from an external environment, wherein the front cover is provided by bonding patterned glass or an ethylene-chloro-tri-fluoro ethylene (ECTFE) film such that the high-power shingled photovoltaic module is usable as an exterior design element of a building through an increase in esthetics and a reduction in reflectance.

The high-power shingled photovoltaic module according to the present invention may further include an aluminum honeycomb formed in a honeycomb-like hexagonal shape to strengthen mechanical durability of the photovoltaic module and insulate the photovoltaic module, a second backsheet provided below the aluminum honeycomb, a first adhesive layer provided to bond the first backsheet and the aluminum honeycomb, and a second adhesive layer provided to bond the aluminum honeycomb and the second backsheet.

In the high-power shingled photovoltaic module according to the present invention, the first adhesive layer and the second adhesive layer may each be provided as an ethylene vinyl acetate (EVA), ionomer, or poly olefin elastomer (POE) film to eliminate a delamination phenomenon due to a difference in thermal expansion.

In the high-power shingled photovoltaic module according to the present invention, the first backsheet and the second backsheet may be formed of E-glass fiber (220 g/m²) and resin to strengthen insulation and mechanical durability and are formed to have a thickness of 0.7 mm to 0.8 mm.

The high-power shingled photovoltaic module according to the present invention may further include a heat dissipation steel plate formed on a bottom surface of the first backsheet to emit heat generated in the solar panel, and a first adhesive layer provided to bond the first backsheet and the heat dissipation steel plate, wherein the heat dissipation steel plate is provided as a zinc-coated steel plate, and a junction box is provided on a rear surface of the heat dissipation steel plate.

In the high-power shingled photovoltaic module according to the present invention, when the high-power shingled photovoltaic module is installed on a roof, both side surfaces of the heat dissipation steel plate may be bent toward the solar panel to facilitate assembly work.

In the high-power shingled photovoltaic module according to the present invention, the first sealant, the second sealant, and the first bonding layer may each be formed of EVA or POE for interlayer bonding.

In order to achieve the above object, a method of manufacturing a high-power shingled photovoltaic module according to the present invention, includes (a) providing a front cover, a solar panel with a shingled array structure, a backsheet, a plurality of sealants, a first adhesive layer, a second adhesive layer, and an aluminum honeycomb, (b) stacking the front cover, the solar panel with the shingled array structure, the backsheet, the plurality of sealants, the first and second adhesive layers, and the aluminum honeycomb provided in operation (a) and providing a stack, and (c) thermally pressing the stack provided in operation (b), wherein the front cover is provided by bonding patterned glass or an ECTFE film such that the high-power shingled photovoltaic module is usable as an exterior design element of a building through an increase in esthetics and a reduction in reflectance, and the photovoltaic module is manufactured as one set of modules through the thermal pressing in operation (c).

In order to achieve the above object, a method of manufacturing a high-power shingled photovoltaic module according to the present invention, includes (a) providing a front cover, a solar panel with a shingled array structure, a backsheet, a plurality of sealants, a first adhesive layer, and a heat dissipation steel plate, (b) stacking the front cover, the solar panel with the shingled array structure, the backsheet, the plurality of sealants, the first adhesive layer, and the heat dissipation steel plate provided in operation (a) and providing a stack, and (c) thermally pressing the stack provided in operation (b), wherein the front cover is provided by bonding patterned glass or an ECTFE film such that the high-power shingled photovoltaic module is usable as an exterior design element of a building through an increase in esthetics and a reduction in reflectance, and the photovoltaic module is manufactured as one set of modules through the thermal pressing in operation (c).

### Advantageous Effects

As described above, according to a high-power shingled photovoltaic module applicable to building-integrated photovoltaics (BIPV) and a method of manufacturing the same according to the present invention, a front cover is provided by bonding a patterned ethylene-chloro-trifluoro ethylene (ECTFE) film to manufacture a module as a solid and lightweight building material-integrated type, thereby obtaining an effect of improving the aesthetics of the high-power shingled photovoltaic module and reducing the reflectance thereof to use the high-power shingled photovoltaic module as an exterior design element of a building.

In addition, according to a high-power shingled photovoltaic module applicable to BIPV and a method of manufacturing the same according to the present invention, an aluminum honeycomb is provided, thereby obtaining an effect of strengthening durability against physical shock occurring during a transportation or installation process of a photovoltaic module.

In addition, according to a high-power shingled photovoltaic module applicable to BIPV and a method of manufacturing the same according to the present invention, a heat dissipation steel plate formed on a bottom surface of a backsheet layer is provided to dissipate heat generated from a solar panel, thereby obtaining an effect of preventing degradation in power due to a temperature rise in a shingled silicon photovoltaic module with power that is increased by 20% per the same area.

### DESCRIPTION OF DRAWINGS

FIG. 1 is a view for describing a structure of a stack for a high-power shingled photovoltaic module applicable to building-integrated photovoltaics (BIPV) according to a first embodiment of the present invention.

FIG. 2 is a front photograph of a photovoltaic module manufactured using the stack shown in FIG. 1.

FIG. 3 is a photograph showing a structure of an aluminum honeycomb shown in FIG. 1.

FIG. 4 shows graphs of results of a potential induced degradation (PID) test on the high-power shingled photovoltaic module applicable to BIPV according to the first embodiment of the present invention.

FIG. 5 is a flowchart for describing an example of a process of manufacturing the high-power shingled photovoltaic module applicable to BIPV according to the first embodiment of the present invention.

FIG. 6 is a view for describing a structure of a stack for a high-power shingled photovoltaic module applicable to BIPV according to a second embodiment of the present invention.

FIG. 7 is a photograph of a rear surface of a photovoltaic module manufactured using the stack shown in FIG. 6.

FIG. 8 is a graph showing the power of the high-power shingled photovoltaic module applicable to BIPV according to the second embodiment of the present invention.

FIG. 9 is a graph showing a relationship between power and a temperature rise according to the second embodiment of the present invention.

FIG. 10 is a flowchart for describing an example of a process of manufacturing the high-power shingled photovoltaic module applicable to BIPV according to the second embodiment of the present invention.

FIG. 11 is a cross-sectional view of a fixing rail and a bending structure of a roof-type module to which the high-power shingled photovoltaic module applicable to BIPV according to the second embodiment of the present invention is applied.

FIG. 12 is a cross-sectional view of a state in which the high-power shingled photovoltaic module applicable to BIPV according to the second embodiment of the present invention is mounted on the fixing rail shown in FIG. 11.

### MODES OF THE INVENTION

The above-described and other objects and new features of the present invention will be further clarified from the description of the present specification and accompanying drawings.

As used herein, the term “wafer” is a wafer for solar cells and is formed of single crystal or polycrystalline silicon. The term “photovoltaic structure” may be a device that may convert light into electricity and may include a plurality of semiconductors or other types of materials. The term “solar cell” may have a photovoltaic (PV) structure, may be provided in a form in which electrodes are screen-printed on a p-type silicon substrate, may be formed through passivated emitter and rear side contact (p-PERC), hetrojunction with intrinsic thin layer (n-HIT), passivated emitter and rear totally diffused (n-PERT), or charge selective contact (CSC), and may be a PV structure manufactured on a semiconductor wafer or substrate (for example, silicone) or one or more thin films manufactured on a substrate (for example, glass, plastic, metal, or any other material capable of supporting a PV structure).

In addition, the term “shingled array structure” may be a string structure in which, in order to increase the conversion efficiency and power per unit of a solar cell module, a solar cell equipped with front and rear electrodes is cut to form a plurality of strips, and the front and rear electrodes are bonded and connected with a conductive adhesive.

In addition, the term “PV module” is a module in which a plurality of solar cell strings with a shingled array structure are electrically connected on a frame, glass is positioned on a front surface, an ethylene vinyl acetate (EVA) sheet is formed on a rear surface, and a filler or the like is disposed at an intermediate to form a solar panel.

Hereinafter, embodiments according to the present invention will be described with reference to the drawings.

### First Embodiment

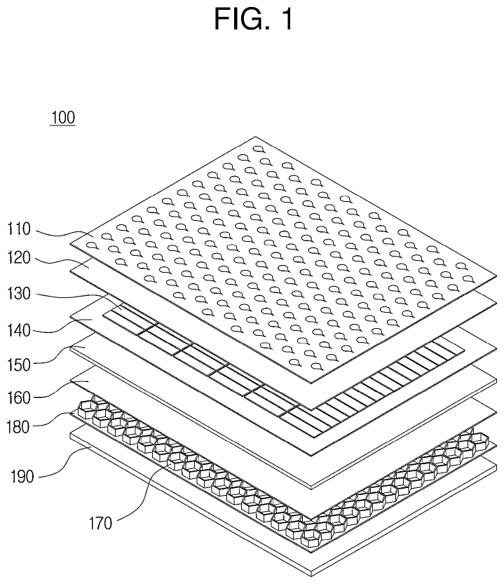

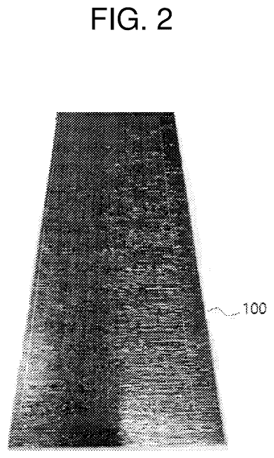

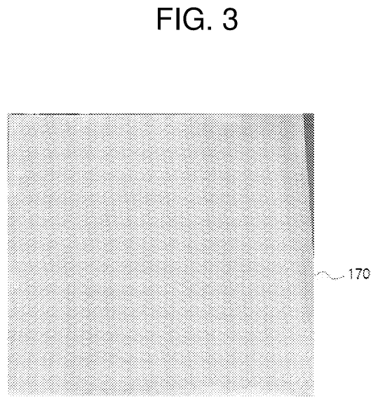

FIG. 1 is a view for describing a structure of a stack for a high-power shingled PV module applicable to building-integrated photovoltaics (BIPV) according to a first embodiment of the present invention. FIG. 2 is a front photograph of a PV module manufactured using the stack shown in FIG. 1. FIG. 3 is a photograph showing a structure of an aluminum honeycomb shown in FIG. 1.

As shown in FIG. 1, the stack for manufacturing a high-power shingled PV module 100 according to the first embodiment of the present invention includes a front cover 110, a first sealant 120, a solar panel 130 with a shingled array structure, a second sealant 140, a first backsheet 150, a first adhesive layer 160, an aluminum honeycomb 170, a second adhesive layer 180, and a second backsheet 190 which are sequentially stacked from above. The front cover 110, the first sealant 120, the second sealant 140, the first backsheet 150, the first adhesive layer 160, the aluminum honeycomb 170, the second adhesive layer 180, and the second backsheet 190 may be provided to have sizes corresponding to each other. For example, the PV module 100 as shown in FIG. 2 may be provided to have a size of 1,050 mm×1,000 mm×6.2 mm (W×L×H) and a total weight of about 9 kg.

In order to increase the aesthetics and reduce reflectance of the high-power shingled PV module 100 for use the high-power shingled PV module 100 as an external design element of a building, the front cover 110 may be provided, for example, by bonding glass patterned in a rainy pattern as shown in FIGS. 1 and 2, or an ethylene-cloro-tri-fluoro ethylene (ECTFE) film for protecting the PV module from the external environment for a long time.

The first sealant 120 and the second sealant 140 are each provided to protect fragile solar cells and circuits from shock and for interlayer bonding, and for example, EVA or a poly olefin elastomer (POE) that transmits sunlight may be applied. However, the present invention is not limited thereto, and any material may be applied as the sealant of the present invention as long as the material serves as an electrically insulating sealant, has a bonding function, and has light transmittance. The first sealant 120 and the second sealant 140 are attached to front and rear surfaces of the solar panel 130 with the shingled array structure to protect the solar panel 130 from external environments such as moisture infiltration and have a buffering function of preventing damage. That is, the first sealant 120 is stacked on the solar panel to protect the solar panel 130, and the second sealant 140 is stacked below the solar panel to protect the solar panel 130.

For example, in order to increase the conversion efficiency and power per unit of a solar cell module, the solar panel 130 with the shingled array structure may have a string structure in which a solar cell equipped with a front electrode and a back electrode is cut to form a plurality of strips, and the front and back electrodes are bonded and connected with a conductive adhesive. The solar panel 130 with the shingled array structure can increase power by 20% per the same area compared to a common solar panel.

The first backsheet 150 and the second backsheet 170 may be sheets for strengthening insulation and mechanical durability, may be formed of a material commonly used in a battery module field, for example, E-glass fiber (220 g/m²) and resin, and may be formed to have a thickness of 0.7 mm to 0.8 mm. The first backsheet 150 and the second backsheet 170 are provided to protect a solar cell from external environments such as heat, humidity, and ultraviolet rays and increase the efficiency of a module through the re-reflection of sunlight introduced through the solar cell.

In addition, the first adhesive layer 160 is provided to bond the first backsheet 150 and the aluminum honeycomb 170, and the second adhesive layer 180 is provided to bond the aluminum honeycomb 170 and the second backsheet 190. The first adhesive layer 160 and the second adhesive layer 180 are provided to eliminate a delamination phenomenon due to a difference in thermal expansion, and an EVA, ionomer, or POE film may be applied.

The aluminum honeycomb 170 is formed in a honeycomb-like hexagonal shape as shown in FIG. 3 to strengthen mechanical durability and for insulating, uses aluminum as a core material, is formed to have a thickness of 3 mm to 6 mm to absorb energy shock, and is provided to absorb shock that occurs when the PV module is transported or installed.

Meanwhile, a junction box for transmitting electricity generated by the solar panel 130 may be provided below the second backsheet 190.

In addition, the high-power shingled PV module 100 applicable to BIPV according to the first embodiment of the present invention may further include a frame provided on the front cover 110 and surrounding a perimeter of the module, and the frame may be provided to protect the module and may be formed of, for example, a synthetic polymer material to reduce weight or an aluminum material to reduce weight and add a heat dissipation function.

As shown in FIG. 1, the stack, in which the front cover 110, the first sealant 120, the solar panel 130 with the shingled array structure, the second sealant 140, the first backsheet 150, the first adhesive layer 160, the aluminum honeycomb 170, the second adhesive layer 180, and the second backsheet 190 are sequentially stacked from above, may be pressed and heated to form the PV module 100. A side surface of the PV module 100 formed in this way is provided such that respective layers are in close contact with each other.

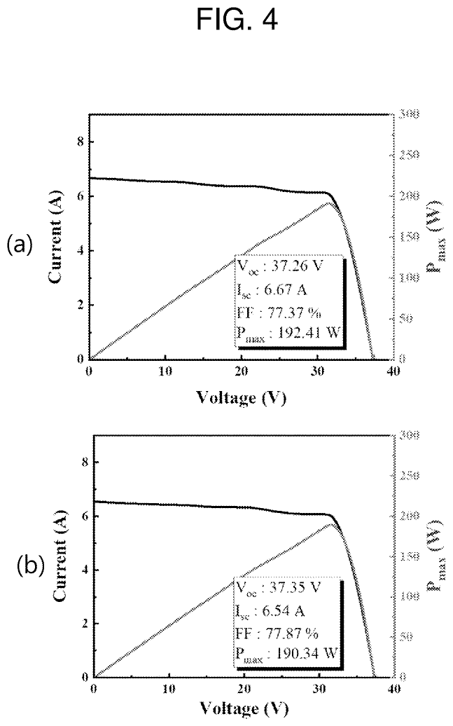

For example, as results of a potential induced degradation (PID) test on the PV module 100 formed to have a size of 1,050 mm×1,000 mm×6.2 mm (W×L×H), as shown in FIG. 4, it could be seen that the electrical durability was excellent. FIG. 4 shows graphs of the results of the PID test on the high-power shingled PV module applicable to BIPV according to the first embodiment of the present invention.

That is, in the high-power shingled PV module applicable to BIPV according to the first embodiment of the present invention, as shown in FIG. 4A, compared to module power characteristics such as an open-circuit voltage V_{oc} of 37.26 V, a short-circuit current I_{sc} of 6.67 A, a curve factor FF of 77.37%, and a measured power Pₘₐₓ of 192.41 W before PID which refers to a power degradation phenomenon induced by a high potential difference, as shown in FIG. 4B, the module power characteristics after the PID, such as an open-circuit voltage V_{oc} of 37.35 V, a short-circuit current I_{sc} of 6.54 A, a curve factor FF of 77.87%, and a measured power Pₘₐₓ of 190.34 W, were obtained, and thus it could be confirmed that a power reduction rate was 1.09% to exhibit excellent electrical durability.

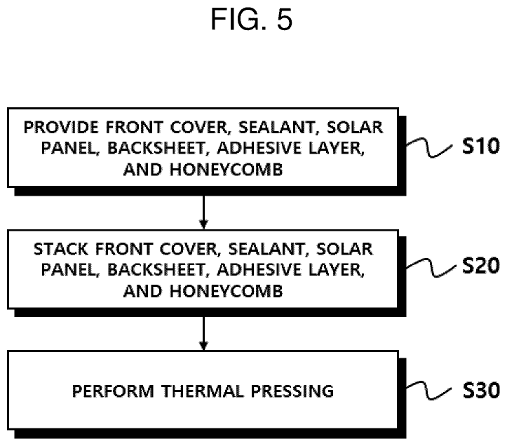

Next, an example of a process of manufacturing a high-power shingled building material integrated PV module for building facades according to the first embodiment of the present invention will be described with reference to FIG. 5.

FIG. 5 is a flowchart for describing an example of a process of manufacturing the high-power shingled PV module applicable to BIPV according to the first embodiment of the present invention.

First, the front cover 110, the first sealant 120, the solar panel 130 with the shingled array structure, the second sealant 140, the first backsheet 150, the first adhesive layer 160, the aluminum honeycomb 170, the second adhesive layer 180, and the second backsheet 190 are each provided (S10) and are sequentially stacked as shown in FIG. 1 to form a stack (S20).

Next, the stack provided in operation S20 is thermally pressed (S30).

In operation S30, the stack is placed in a vacuum pack, and a pressure of 30 kPa is applied at a temperature of 120° C. to 150° C. for 10 minutes to 15 minutes, preferably, a pressure of 30 kPa is applied at a temperature of 140° C. for 660 seconds to uniformly perform a lamination process, thereby manufacturing the high-power shingled PV module 100 according to the first embodiment of the present invention.

Meanwhile, the stacking in operation S20 may be performed for, for example, 9 minutes, and the thermal pressing in operation S30 may be performed at a temperature of 140° C. for 11 minutes to manufacture one set of modules.

The high-power shingled PV module applicable to BIPV according to the first embodiment of the present invention is manufactured by wrapping a perimeter of the high-power shingled PV module 100 manufactured as described above with a frame.

### Second Embodiment

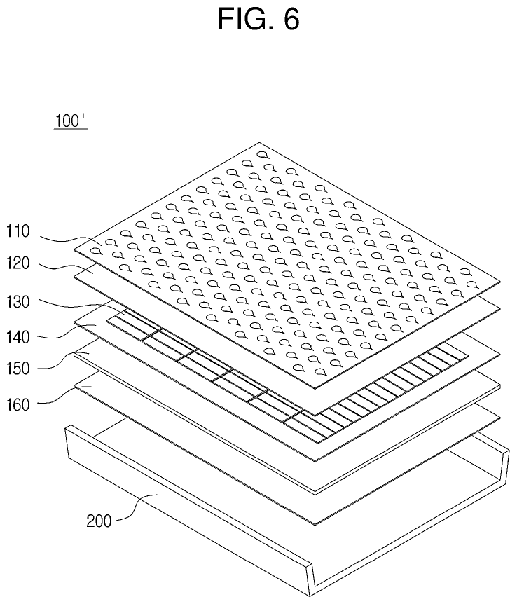

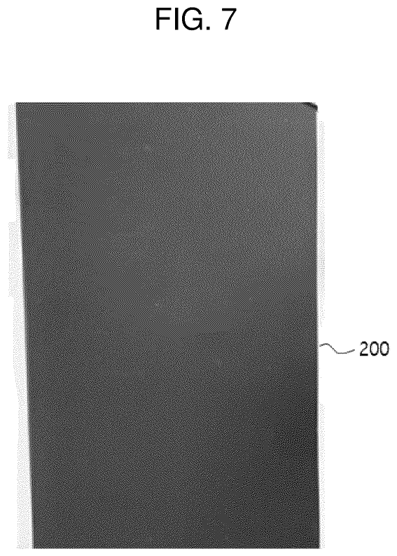

FIG. 6 is a view for describing a structure of a stack for a high-power shingled PV module applicable to BIPV according to a second embodiment of the present invention. FIG. 7 is a photograph of a rear surface of a PV module manufactured using the stack shown in FIG. 6.

As shown in FIG. 6, the stack for manufacturing a high-power shingled PV module 100′ according to the second embodiment of the present invention includes a front cover 110, a first sealant 120, a solar panel 130 with a shingled array structure, a second sealant 140, a first backsheet 150, a first adhesive layer 160, and a heat dissipation steel plate 200 which are sequentially stacked from above. The front cover 110, the first sealant 120, the second sealant 140, the first backsheet 150, and the first adhesive layer 160 may be provided to have sizes corresponding to each other.

As in the above-described first embodiment, in order to increase the aesthetics and reduce reflectance of the high-power shingled PV module 100′ to use the high-power shingled PV module 100′ as an external design element of a building, the front cover 110 may be provided, for example, by bonding glass patterned in a rainy pattern as shown in FIG. 6, or an ECTFE film for protecting the PV module from the external environment for a long time.

The first sealant 120 and the second sealant 140 are each provided to protect fragile solar cells and circuit from shock and for interlayer bonding, and for example, EVZ or a POE that transmits sunlight may be applied. In addition, like the first sealant 120, EVA or a POE may be applied to the first adhesive layer 160, and the first adhesive layer 160 may be provided to bond the first backsheet 150 and the heat dissipation steel plate 200.

In order to increase the conversion efficiency and power per unit of a solar cell module, the solar panel 130 with the shingled array structure may have a string structure in which a solar cell equipped with a front electrode and a back electrode is cut to form a plurality of strips, and the front and back electrodes are bonded and connected with a conductive adhesive.

The first backsheet 150 may be formed of an aluminum or plastic material to protect a solar cell from external environments such as heat, humidity, and ultraviolet rays and may be provided to increase the efficiency of a module through the re-reflection of sunlight introduced through the solar cell.

The heat dissipation steel plate 200 may be provided as a zinc-coated steel plate to impart heat absorption and/or heat dissipation characteristics, and a heat dissipation coating layer that imparts excellent heat dissipation, processability, corrosion resistance, solvent resistance, coating adhesion, and gloss may be provided on one surface or both surfaces of such a zinc-coated steel plate. The heat dissipation steel plate 200 may be, for example, a hot-dip galvanized steel plate (galvanizing steel (GI)), an alloyed hot-dip galvanized steel plate (galvannealed steel (GA)), or an electrogalvanized steel plate.

In addition, as shown in FIG. 6, the heat dissipation steel plate 200 is provided by bending both sides, and thus for example, when the heat dissipation steel plate 200 is installed on a roof, assembly work may be easily performed. Meanwhile, although the heat dissipation steel plate 200 is illustrated n FIG. 6 as being provided to have the same size as the first backsheet 150 or the like, the present invention is not limited thereto, and the heat dissipation steel plate 200 may be provided longer than the first backsheet 150. When the high-power shingled PV module 100′ provided in this way is installed on a roof, only a bent portion of an upper portion of the heat dissipation steel plate 200, on which the solar panel 130 is not provided, may be cut, and a lower portion of the high-power shingled PV module may be installed to overlap the upper portion, and thus construction work may be facilitated.

A rear surface of the heat dissipation steel plate 200 is as shown in FIG. 7, and a design for applying a junction box on the rear surface may be secured.

In the high-power shingled PV module 100′ according to the second embodiment of the present invention, as shown in FIG. 6, the stack, in which the front cover 110, the first sealant 120, the solar panel 130 with the shingled array structure, the second sealant 140, the first backsheet 150, the adhesive layer 160, and the dissipation steel plate 200 are sequentially stacked from above, is pressed and heated to form a module in which respective layers are in close contact with each layer. Thermal pressing in the pressing and heating was performed at a temperature of 130° C. to 150° C. for 10 minutes to 15 minutes, and one set of modules was manufactured.

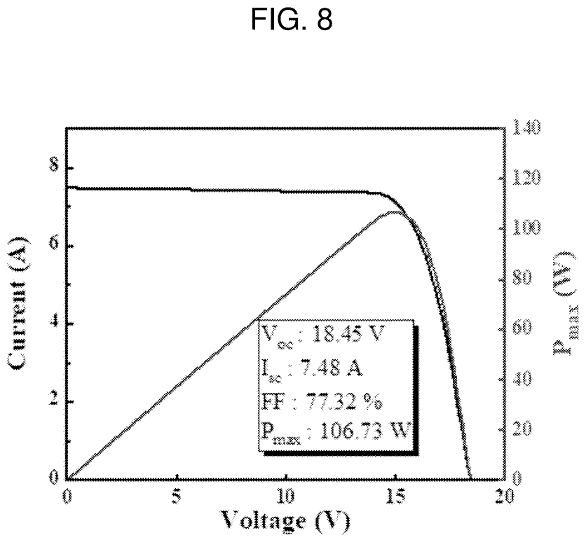

The power of the high-power shingled PV module applicable to BIPV according to the second embodiment of the present invention was measured. FIG. 8 is a graph showing the power of the high-power shingled PV module applicable to BIPV according to the second embodiment of the present invention.

That is, in the high-power shingled PV module applicable to BIPV according to the second embodiment of the present invention, as shown in FIG. 8, module power characteristics such as an open-circuit voltage V_{oc} of 18.45 V, a short-circuit current I_{sc} of 7.48 A, a curve factor FF of 77.32%, and a measured power Pₘₐₓ of 106.73 W were obtained.

In addition, the power conversion according to a temperature of the PV module provided as described above was tested.

When the high-power shingled PV module applicable to BIPV according to the second embodiment of the present invention is installed on a roof (RT), it is necessary to prevent a decrease in power due to an increase in module temperature caused by the influence of direct sunlight. Comparison was made with a temperature and a power reduction rate of a common PV module (power reduction of 0.5% per 1° C. rise).

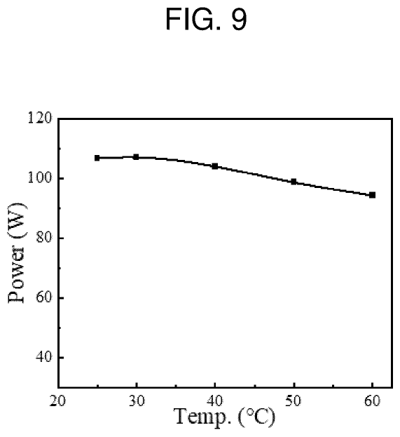

Table 1 below shows a reduction rate and a theoretically expected reduction rate in the high-power shingled PV module applicable to BIPV according to the second embodiment of the present invention. FIG. 9 is a graph showing a relationship between power and a temperature rise according to the second embodiment of the present invention.

TABLE 1

| Temperature (° C.) | RT | 30 | 40 | 50 | 60 |
|---|---|---|---|---|---|
| Power (W) | 106.73 | 106.95 | 103.92 | 95.67 | 94.25 |
| Actual reduction | 0 | −0.21 | 2.63 | 10.36 | 11.69 |
| rate (%) | | | | | |
| Expected reduction | 0 | 2.5 | 7.5 | 12.5 | 17.5 |
| rate (%) | | | | | |

As can be seen from Table 1 and FIG. 9, it could be seen that a power reduction rate according to a temperature of the high-power shingled PV module according to the second embodiment of the present invention was improved as compared to the common module. That is, as can be seen from Table 1 and FIG. 9, the best power reduction rate was 2.63% when a module front temperature was 40° C. under a standard test condition (STC (25° C.)). As described above, in the high-power shingled PV module applicable to BIPV according to the second embodiment of the present invention, the heat dissipation steel plate 200 may be applied to the rear of the module to improve the thermal characteristics of the module and provide a bending structure that is easy to install, and thus when the module is installed on an RF, an operator can easily and quickly perform work.

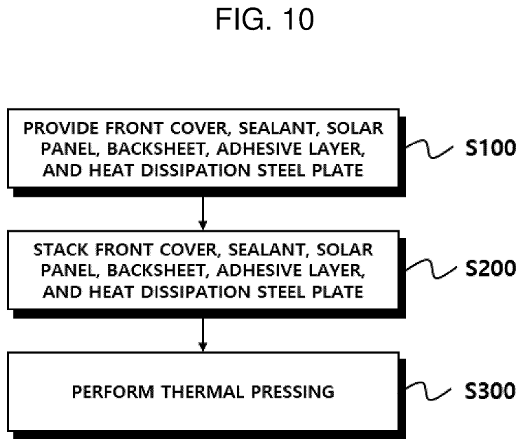

Next, an example of a process of manufacturing the high-power shingled PV module applicable to BIPV according to the second embodiment of the present invention will be described with reference to FIG. 10.

FIG. 10 is a flowchart for describing an example of the process of manufacturing the high-power shingled PV module applicable to BIPV according to the second embodiment of the present invention.

First, the front cover 110, the first sealant 120, the solar panel 130 with the shingled array structure, the second sealant 140, the first backsheet 150, the first adhesive layer 160, and the heat dissipation steel plate 200 are each provided (S100) and are sequentially stacked as shown in FIG. 6 to form a stack (S200).

Next, the stack provided in operation S200 is thermally pressed (S300).

In operation S300, as in the first embodiment, the stack is placed in a vacuum pack, and a pressure of 30 kPa is applied at a temperature of 120° C. to 150° C. for 10 minutes to 15 minutes, preferably, a pressure of 30 kPa is applied at a temperature of 140° C. for 660 seconds to uniformly perform a lamination process, thereby manufacturing the high-power shingled PV module 100′ according to the second embodiment of the present invention.

Meanwhile, the stacking in operation S200 may be performed for, for example, 9 minutes, and the thermal pressing in operation S30 may be performed at a temperature of 140° C. for 11 minutes to manufacture one set of modules.

The high-power shingled PV module applicable to BIPV according to the second embodiment of the present invention is manufactured by wrapping a perimeter of the high-power shingled PV module 100′ manufactured as described above with a frame.

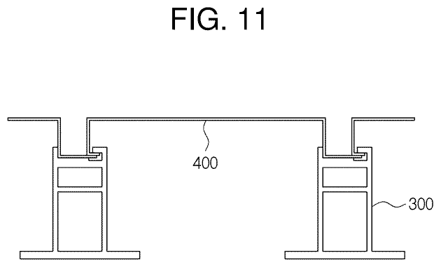

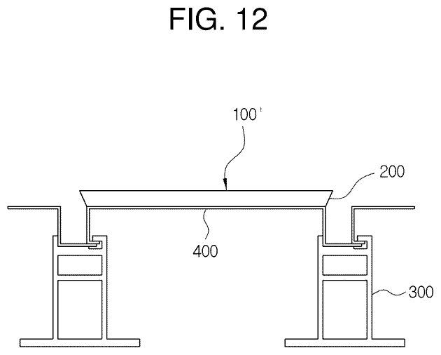

Next, an example of a structure in which the high-power shingled PV module according to the second embodiment of the present invention is mounted on an RF will be described with reference to FIGS. 11 and 12.

FIG. 11 is a cross-sectional view of a fixing rail and a bending structure of a roof-type module to which the high-power shingled PV module applicable to BIPV according to the second embodiment of the present invention is applied. FIG. 12 is a cross-sectional view of a state in which the high-power shingled PV module applicable to BIPV according to the second embodiment of the present invention is mounted on the fixing rail shown in FIG. 11.

In the fixing rail and bending structure of the roof-type module to which the high-power shingled PV module applicable to BIPV according to the second embodiment of the present invention is applied, as shown in FIG. 11, for example, a plurality of fixing rails 300 fixed to an RF and a support plate 400 mounted between the fixing rails 300 are provided.

As shown in FIG. 11, lower wing portions of the plurality of fixing rails 300 are fixed to the RF at certain intervals using screws or the like, and the support plate 400 is fixed to an upper concave portion. The support plate 400 is provided with a flat portion maintained between the fixing rails 300, and as shown in FIG. 12, the shingled PV module is mounted on the flat portion. In addition, one side of the support plate 400 is inserted into a concave portion of one fixing rail, and the other side thereof is inserted into a concave portion of another fixing rail. Meanwhile, as shown in FIG. 11, one side of the support plate 400 inserted into the concave portion may be mounted to overlap the other side of another support plate, thereby securing rigidity and forming a side hole for heat dissipation.

By providing the support plate 400 with such a structure, the support plate can be easily mounted on the fixing rail 300. In addition, as shown in FIG. 12, the PV module including the heat dissipation steel plate 200 provided by bending both sides according to the present invention may be easily mounted on the support plate 400.

Although the invention made by the present inventor has been described in detail on the basis of the embodiments, the present invention is not limited to the embodiments and may have various modifications in the scope without departing from the spirit thereof.

### INDUSTRIAL APPLICABILITY

By using a high-power shingled PV module applicable to BIPV and a method of manufacturing the same according to the present invention, the high-power shingled PV module can be used as an external design element of a building by increasing the aesthetics and reducing the reflectance of the high-power shingled PV module.

1. A high-output shingled photovoltaic module applicable to building-integrated photovoltaics (BIPV), comprising:
a solar panel having a shingled array structure;
a first sealant stacked on the solar panel to protect the solar panel;
a second sealant stacked below the solar panel to protect the solar panel;
a front cover stacked on the first sealant to transmit sunlight and protect the first sealant;
a first backsheet stacked below the second sealant to protect the solar panel from an external environment, and
an aluminum honeycomb formed in a honeycomb-like hexagonal shape to strengthen mechanical durability of the photovoltaic module and insulate the photovoltaic module,
wherein the front cover is provided by bonding a patterned ethylene-chloro-tri-fluoro ethylene (ECTFE) film such that the high-power shingled photovoltaic module is usable as an exterior design element of a building through an increase in esthetics and a reduction in reflectance, and a module is manufactured as a solid and lightweight building material-integrated type.

2. The high-output shingled photovoltaic module of claim 1, further comprising:
a second backsheet provided below the aluminum honeycomb;
a first adhesive layer provided to bond the first backsheet and the aluminum honeycomb; and
a second adhesive layer provided to bond the aluminum honeycomb and the second backsheet.

3. The high-output shingled photovoltaic module of claim 2, wherein the first adhesive layer and the second adhesive layer are each provided as an ethylene vinyl acetate (EVA), ionomer, or poly olefin elastomer (POE) film to eliminate a delamination phenomenon due to a difference in thermal expansion.

4. The high-output shingled photovoltaic module of claim 2, wherein the first backsheet and the second backsheet are formed of E-glass fiber of 220 g/m² and resin to strengthen insulation and mechanical durability and are formed to have a thickness of 0.7 mm to 0.8 mm.

5. A high-output shingled photovoltaic module applicable to building-integrated photovoltaics (BIPV), comprising:
a solar panel having a shingled array structure;
a first sealant stacked on the solar panel to protect the solar panel;
a second sealant stacked below the solar panel to protect the solar panel;
a front cover stacked on the first sealant to transmit sunlight and protect the first sealant; and
a first backsheet stacked below the second sealant to protect the solar panel from an external environment; and
a heat dissipation steel plate formed on a bottom surface of the first backsheet to emit heat generated in the solar panel,
wherein the heat dissipation steel plate is provided as a zinc-coated steel plate, and
the front cover is provided by bonding a patterned ethylene-chloro-tri-fluoro ethylene (ECTFE) film such that the high-power shingled photovoltaic module is usable as an exterior design element of a building through an increase in esthetics and a reduction in reflectance.

6. The high-output shingled photovoltaic module of claim 5, further comprising:
a first adhesive layer provided to bond the first backsheet and the heat dissipation steel plate; and
a junction box is provided on a rear surface of the heat dissipation steel plate.

7. The high-output shingled photovoltaic module of claim 5, wherein the first sealant, the second sealant, and the first bonding layer are each formed of ethylene vinyl acetate (EVA) or a poly olefin elastomer (POE) for interlayer bonding.

8. A method of manufacturing a high-output shingled photovoltaic module applicable to building-integrated photovoltaics (BIPV), the method comprising:
(a) providing a front cover, a solar panel with a shingled array structure, a backsheet, a plurality of sealants, a first adhesive layer, a second adhesive layer, and an aluminum honeycomb;
(b) stacking the front cover, the solar panel with the shingled array structure, the backsheet, the plurality of sealants, the first and second adhesive layers, and the aluminum honeycomb provided in operation (a) and providing a stack; and
(c) thermally pressing the stack provided in operation (b),
wherein the front cover is provided by bonding a patterned ethylene-chloro-tri-fluoro ethylene (ECTFE) film such that the high-power shingled photovoltaic module is usable as an exterior design element of a building through an increase in esthetics and a reduction in reflectance, and a module is manufactured as a solid and lightweight building material-integrated type, and
the photovoltaic module is manufactured as one set of modules by the thermal pressing in operation (c).

9. A method of manufacturing a high-output shingled photovoltaic module applicable to building-integrated photovoltaics (BIPV), the method comprising:
(a) providing a front cover, a solar panel with a shingled array structure, a backsheet, a plurality of sealants, a first adhesive layer, and a heat dissipation steel plate;
(b) stacking the front cover, the solar panel with the shingled array structure, the backsheet, the plurality of sealants, the first adhesive layer, and the heat dissipation steel plate provided in operation (a) and providing a stack; and
(c) thermally pressing the stack provided in operation (b),
wherein the heat dissipation steel plate is provided as a zinc-coated steel plate to emit heat generated in the solar panel and is formed on a bottom surface of the first backsheet,
the front cover is provided by bonding a patterned ethylene-chloro-tri-fluoro ethylene (ECTFE) film such that the high-power shingled photovoltaic module is usable as an exterior design element of a building through an increase in esthetics and a reduction in reflectance. and
the photovoltaic module is manufactured as one set of modules by the thermal pressing in operation (c).

10. (canceled)
